(19) United States
(12) Patent Application Publication
(10) Pub. No.: US 2026/0343795 A1
(43) Pub. Date: Oct. 29, 2026

(54) ELECTRONIC DEVICE AND THERMAL CONTROL METHOD THEREOF

(71) Applicant: COMPAL ELECTRONICS, INC., Taipei City (TW)

(72) Inventors: Sheng-Hsiang Huang, Taipei City (TW); Hsin-Chieh Fang, Taipei City (TW); Ching-Ta Wu, Taipei City (TW); Tze-Chin Chen, Taipei City (TW); Ching-Chung Chen, Taipei City (TW)

(73) Assignee: COMPAL ELECTRONICS, INC., Taipei City (TW)

(21) Appl. No.: 19/656,956

(22) Filed: Apr. 23, 2026

Related U.S. Application Data
(60) Provisional application No. 63/796,405, filed on Apr. 29, 2025.

(51) Int. Cl. H05K 7/20; G06F 1/20

(52) U.S. Cl. CPC H05K 7/20209; G06F 1/203; H05K 7/20154; H05K 7/20172; H05K 7/20318; H05K 7/20336

(57) ABSTRACT

An electronic device and a thermal control method thereof are provided. The device includes a body and a heat source, an active fan, a heat pipe, an ionic fan, and two temperature sensors disposed in the body. The heat source includes a processor. The active fan, the ionic fan, and the two temperature sensors are electrically coupled to the processor. The two temperature sensors detect temperatures at different positions of the heat pipe. The processor applies a driving voltage to the ionic fan and determines whether to turn on the active fan based on a determination result of detection signals from the two temperature sensors.

### CROSS-REFERENCE TO RELATED APPLICATION

This application claims the priority benefit of U.S. provisional application serial no. 63/796,405, filed on Apr.29, 2025. The entirety of the above-mentioned patent application is hereby incorporated by reference herein and made a part of this specification.

### BACKGROUND

### Technical Field

The disclosure relates to an electronic device, and particularly relates to an electronic device and a thermal control method thereof.

### Related Art

A laptop is composed of a first body having logical computing capability and a second body having image display capability, wherein the first body is provided with a central processing unit and a graphics processing unit therein, and the central processing unit and the graphics processing unit generate a large amount of heat during operation. In order to quickly discharge the heat out of the first body, the first body is typically provided with an active fan (e.g., a centrifugal fan or an axial fan), a heat pipe, and heat dissipation fins therein to perform forced heat dissipation.

In detail, the active fan may adjust the rotational speed according to load changes, performing low-speed operation in a low load mode and performing high-speed operation in a high load mode. However, low-frequency noise caused by the low-speed operation and high-frequency noise caused by the high-speed operation both negatively affect the operating experience of the user. On the other hand, frequent switching between increase and decrease in rotational speed not only generates additional energy consumption, but also reduces the service life of the active fan.

### SUMMARY

The disclosure provides an electronic device and a thermal control method thereof, which can execute silent heat dissipation to reduce energy consumption in a low load mode, and automatically increase air volume to execute efficient heat dissipation in a high load mode.

The disclosure provides an electronic device, which includes a body and a heat source, an active fan, a heat pipe, an ionic fan, a first temperature sensor, and a second temperature sensor disposed in the body. The body has a first side, a second side opposite to the first side, and an exhaust vent penetrating the second side. The heat source includes at least a processor. The active fan is electrically coupled to the processor. The heat pipe includes an evaporation section and a condensation section. The evaporation section is thermally coupled to the heat source. The condensation section extends along the exhaust vent and has a first position and a second position. The ionic fan includes a driver electrically coupled to the processor and multiple airflow driving modules electrically coupled to the driver. The airflow driving modules are arranged along the condensation section, and the condensation section is disposed between the exhaust vent and the airflow driving modules. The first temperature sensor and the second temperature sensor correspond to the condensation section and are electrically coupled to the processor. The first temperature sensor is configured to detect a temperature at the first position, and the second temperature sensor is configured to detect a temperature at the second position. The processor is configured to control the driver to apply a driving voltage to the airflow driving modules and determine whether to turn on the active fan based on a determination result of the temperature at the first position and the temperature at the second position.

The disclosure provides a thermal control method applicable to the electronic device, which includes the following steps. The driver is controlled to apply the driving voltage to the airflow driving modules by the processor. Whether to turn on the active fan is determined based on the determination result of the temperature at the first position and the temperature at the second position by the processor.

Based on the above, in the electronic device and the thermal control method thereof of the disclosure, the processor controls the ionic fan to be applied with the driving voltage in both the low load mode and the high load mode, and controls the active fan to be turned on in the high load mode. In the low load mode, the ionic fan can execute silent heat dissipation to reduce energy consumption. In the high load mode, based on real-time monitoring of the temperature at the first position and the temperature at the second position of the condensation section, dynamically adjusting a rotational speed of the active fan and the driving voltage of the ionic fan can not only provide optimal heat dissipation measures in stages in response to a real-time status of thermal management, but can also prevent the active fan and the ionic fan from operating at the high rotational speed and the high driving voltage for a prolonged period of time, preventing prolonged high-frequency noise and effectively reducing energy consumption.

In order for the features and advantages of the disclosure to be more comprehensible, the following specific embodiments are described in detail in conjunction with the drawings.

### BRIEF DESCRIPTION OF THE DRAWINGS

FIG. 1A is a schematic view of an electronic device according to an embodiment of the disclosure.

FIG. 1B is a top schematic view of an internal configuration of a first body of FIG. 1A.

FIG. 1C is a partial cross-sectional schematic view of FIG. 1A taken along a section line 1C-1C.

FIG. 1D is a schematic view of FIG. 1A from another viewing angle.

FIG. 1E is an enlarged schematic view of a region 1E of FIG. 1D.

FIG. 2 is a circuit schematic view of an electronic device according to an embodiment of the disclosure.

FIG. 3 is a schematic flowchart of a thermal control method of an electronic device according to an embodiment of the disclosure.

FIG. 4 and FIG. 5 are top schematic views of an internal configuration of a body according to other embodiments of the disclosure.

### DESCRIPTION OF THE EMBODIMENTS

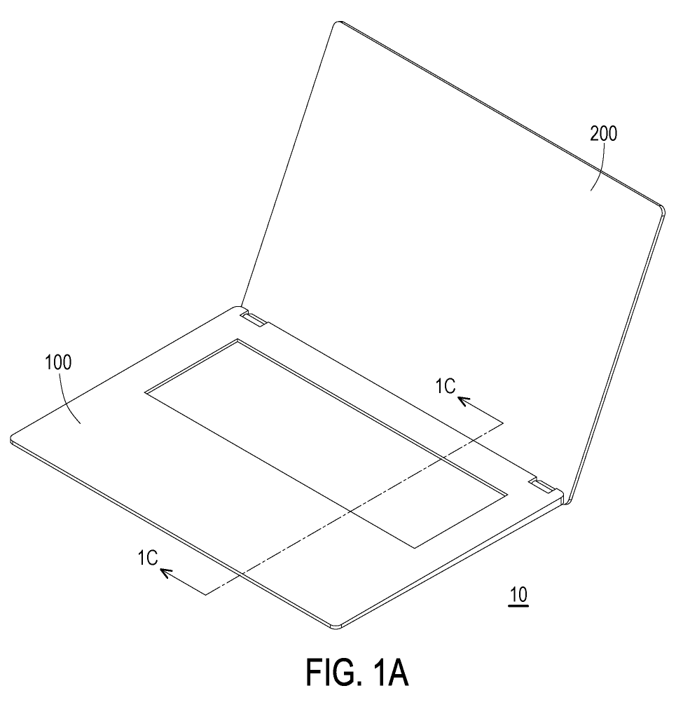

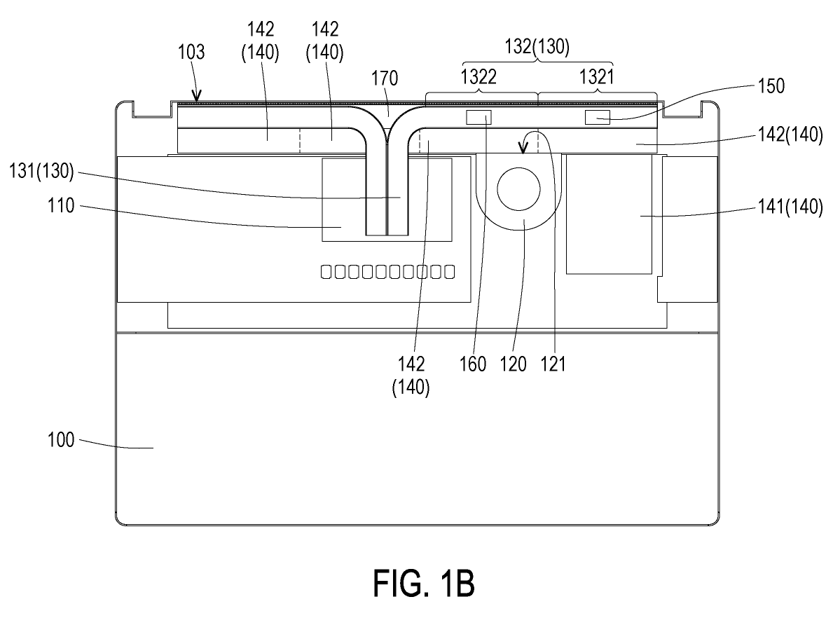

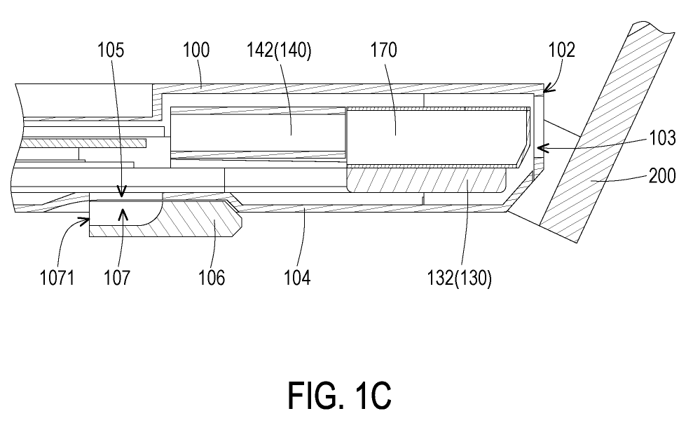

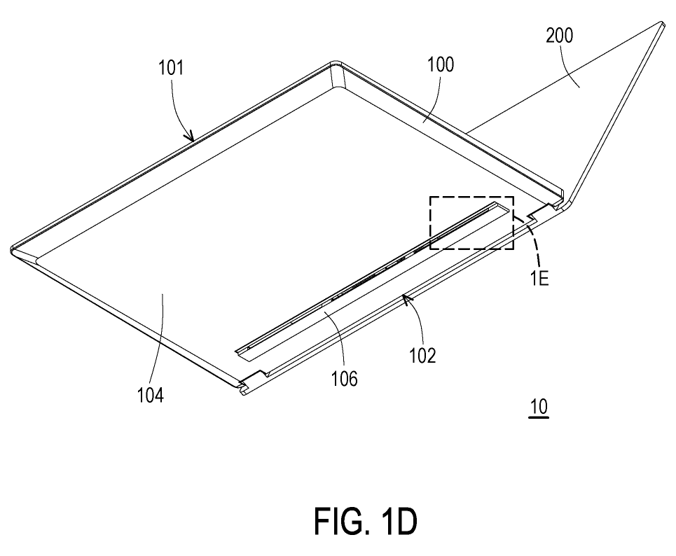

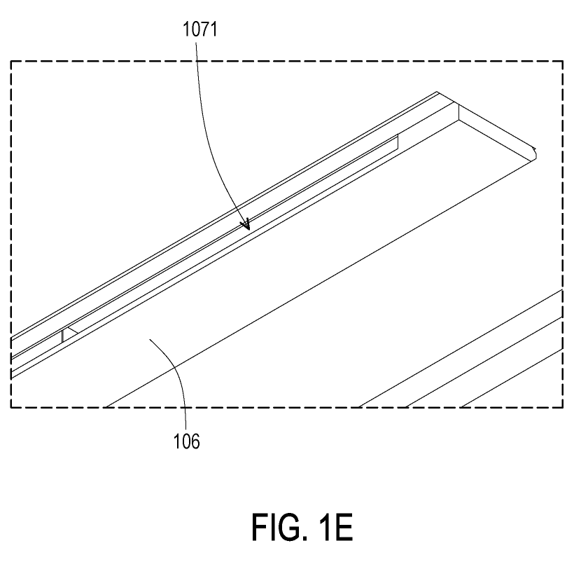

FIG. 1A is a schematic view of an electronic device according to an embodiment of the disclosure. FIG. 1B is a top schematic view of an internal configuration of a first body of FIG. 1A. FIG. 1C is a partial cross-sectional schematic view of FIG. 1A taken along a section line 1C-1C. FIG. 1D is a schematic view of FIG. 1A from another viewing angle. FIG. 1E is an enlarged schematic view of a region 1E of FIG. 1D. Please refer to FIG. 1A to FIG. 1D. In the embodiment, an electronic device 10 may be a laptop and includes a first body 100 with logical computing capability and a second body 200 with image display capability. The second body 200 is pivotally connected to the first body 100 to rotate to open/close relative to the first body 100.

The first body 100 has a first side 101, a second side 102 opposite to the first side 101, and an exhaust vent 103 penetrating the second side 102, and the electronic device 10 is provided with a heat source, an active fan 120, a heat pipe 130, an ionic fan 140, a first temperature sensor 150, a second temperature sensor 160, and heat dissipation fins 170 inside the first body 100. The heat source includes at least a processor 110, such as a central processing unit, a graphics processing unit, a programmable general-purpose or special-purpose microprocessor, a digital signal processor, a programmable controller, a field-programmable gate array, an application-specific integrated circuit, other similar elements, or a combination of the above elements.

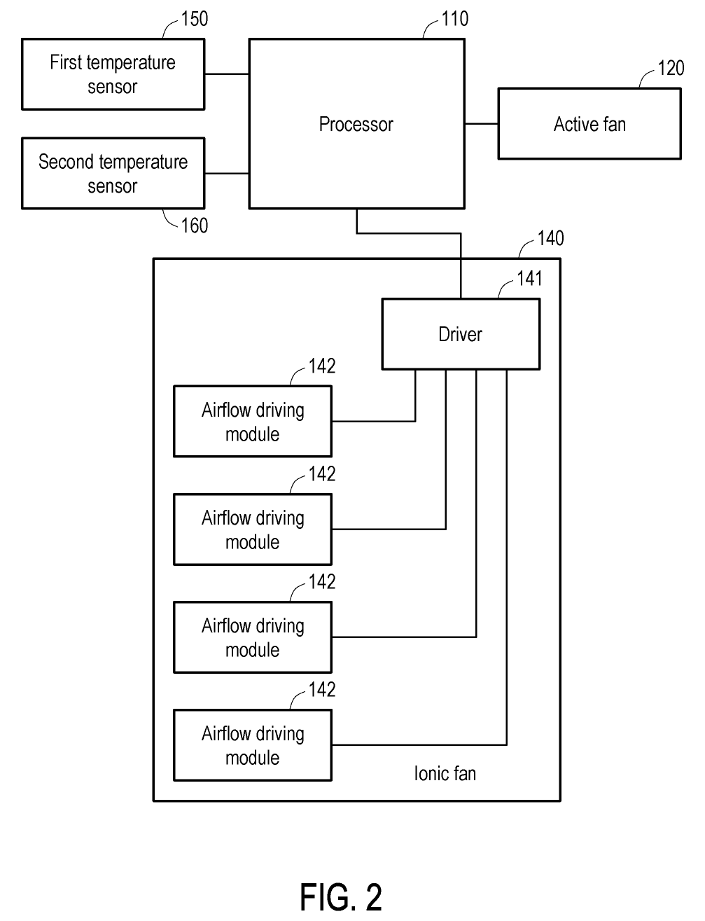

FIG. 2 is a circuit schematic view of an electronic device according to an embodiment of the disclosure. Please refer to FIG. 1B, FIG. 1C, and FIG. 2. The active fan 120 may be a centrifugal fan or an axial fan and is electrically coupled to the processor 110. The heat pipe 130 includes an evaporation section 131 and a condensation section 132, wherein the evaporation section 131 is thermally coupled to the heat source (i.e., the processor 110), and the condensation section 132 extends along the exhaust vent 103.

The ionic fan 140 includes a driver 141 and multiple airflow driving modules 142 arranged along the condensation section 132, wherein the driver 141 is electrically coupled to the processor 110, and the airflow driving modules 142 are electrically coupled to the driver 141. On the other hand, the condensation section 132 laterally extends between the exhaust vent 103 and the airflow driving modules 142.

For example, the airflow driving module 142 may include a flow guide cover and an emitter electrode and a collector electrode disposed opposite to each other in the flow guide cover, wherein the emitter electrode is electrically coupled to the driver 141, and the collector electrode is closer to the exhaust vent 103 than the emitter electrode. The driver 141 applies a driving voltage to the emitter electrode, and the emitter electrode ionizes cool air introduced into the first body 100. Driven by an electric field between the emitter electrode and the collector electrode, air ions move from the emitter electrode toward the collector electrode to form an ion flow, and drive the cool air to form an airflow flowing toward the exhaust vent 103. Such a heat dissipation manner through an ionic airflow is a conventional ionic cooling system, so the internal details of the airflow driving module are omitted from the illustration.

Please refer to FIG. 1B and FIG. 2. The first temperature sensor 150 and the second temperature sensor 160 are electrically coupled to the processor 110, wherein the first temperature sensor 150 is disposed at a first position of the condensation section 132, and the second temperature sensor 160 is disposed at a second position of the condensation section 132. The first temperature sensor 150 and the second temperature sensor 160 are respectively configured to detect temperatures at the first position and the second position of the condensation section 132, and the position of the second temperature sensor 160 on the condensation section 132 is closer to the evaporation section 131 than the first temperature sensor 150.

In the embodiment, the condensation section 132 includes a first part 1321 opposite to the evaporation section 131 and a second part 1322 located between the first part 1321 and the evaporation section 131. The first position where the first temperature sensor 150 is located is at the first part 1321, and the second position where the second temperature sensor 160 is located is at the second part 1322. In other words, the first temperature sensor 150 is disposed corresponding to the first part 1321, and the second temperature sensor 160 is disposed corresponding to the second part 1322. On the other hand, one side of the first part 1321 is provided with one airflow driving module 142, and one side of the second part 1322 is provided with another airflow driving module 142.

Please refer to FIG. 1B and FIG. 1C. The heat dissipation fins 170 are arranged along the exhaust vent 103, and the condensation section 132 of the heat pipe 130 is thermally coupled to the heat dissipation fins 170. Specifically, the heat dissipation fins 170 are laterally arranged between the exhaust vent 103 and the airflow driving modules 142, wherein an arrangement direction of the heat dissipation fins 170 substantially coincides with an extending direction of the condensation section 132 of the heat pipe 130, and the condensation section 132 of the heat pipe 130 is overlappingly soldered onto the heat dissipation fins 170.

Please refer to FIG. 1A to FIG. 1C. An air outlet 121 of the active fan 120 faces the condensation section 132 of the heat pipe 130, the heat dissipation fins 170, and the exhaust vent 103, and heat generated by the heat source (i.e., the processor 110) may be conducted from the evaporation section 131 of the heat pipe 130 to the condensation section 132, and then conducted from the condensation section 132 to the heat dissipation fins 170. Therefore, the cool air introduced into the first body 100 by the active fan 120 forms the airflow flowing toward the exhaust vent 103 in conjunction with the ionic fan 140, performs heat exchange when flowing through the heat dissipation fins 170, and is finally discharged out of the first body 100 from the exhaust vent 103.

Please refer to FIG. 1C to FIG. 1E. The first body 100 further includes a bottom portion 104 and an air inlet 105 penetrating through the bottom portion 104, and the airflow driving modules 142 are laterally arranged between the air inlet 105 and the exhaust vent 103. On the other hand, the first body 100 is provided with a foot pad 106 laterally extending along the air inlet 105 at the bottom portion 104, wherein the foot pad 106 has a flow guide channel 107 communicated with the air inlet 105, and the flow guide channel 107 has an opening 1071 facing the first side 101.

In detail, the external cool air sequentially flows through the opening 1071, the flow guide channel 107, and the air inlet 105, and enters the first body 100. Under the guidance of the flow guide channel 107, the cool air entering the first body 100 from the air inlet 105 may be guided toward the heat dissipation fins 170.

As shown in FIG. 1C and FIG. 1D, the foot pad 106 may support the first body 100, such that a flow guide gap is kept between the bottom portion 104 and a table surface. In addition, the foot pad 106 covers the air inlet 105, that is, the foot pad 106 visually shields the air inlet 105 to optimize the visual appearance of the first body 100.

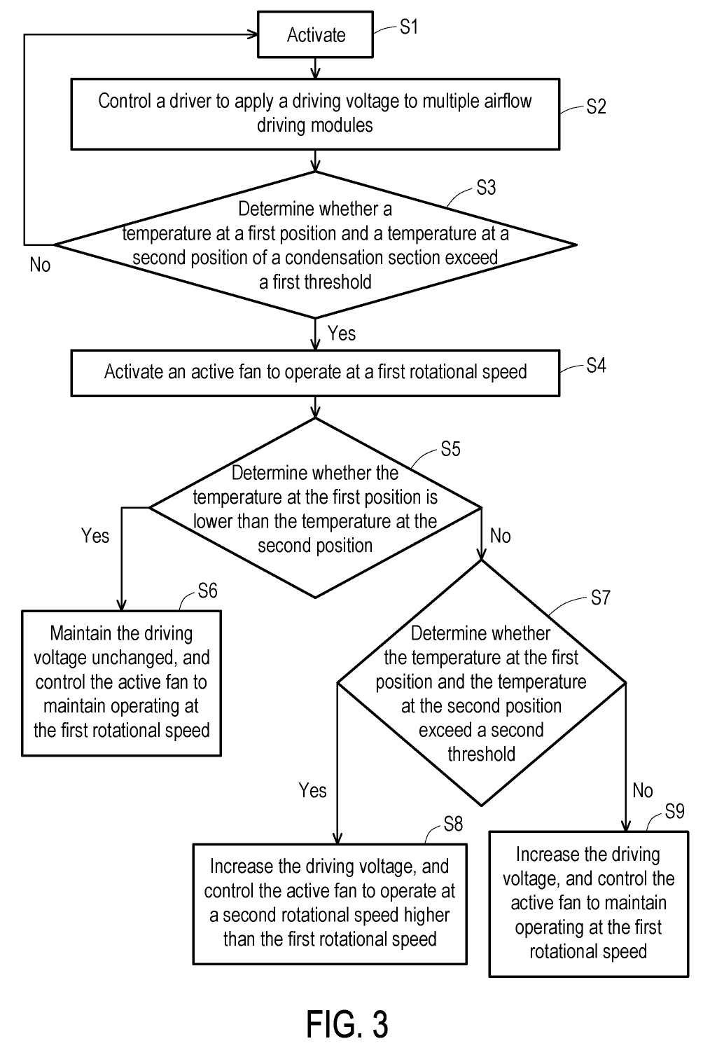

FIG. 3 is a schematic flowchart of a thermal control method of an electronic device according to an embodiment of the disclosure. Please refer to FIG. 1B, FIG. 2, and FIG. 3. In steps S1 to S3, when the electronic device 10 is turned on or woken up from a sleep mode, the processor 110 receives an activation command. Next, the processor 110 controls the driver 141 of the ionic fan 140 to apply a driving voltage to the airflow driving modules 142 to drive the cool air to form the airflow flowing toward the exhaust vent 103, and form hot air to be discharged out of the first body 100 after heat exchange, thereby providing basic heat dissipation efficacy in a low load mode. Furthermore, in the low load mode, silent heat dissipation is executed by the ionic fan 140, and the active fan 120 is not activated, so as to reduce energy consumption and provide an almost noise-free usage environment.

During the period in which the silent heat dissipation is executed by the ionic fan 140, the processor 110 reads detection signals from the first temperature sensor 150 and the second temperature sensor 160, so as to determine whether a temperature at the first position (i.e., the first part 1321) and a temperature at the second position (i.e., the second part 1322) of the condensation section 132 of the heat pipe 130 exceed a first threshold (e.g., 40 Celsius degrees).

If the determination result is that the temperature at the first position and the temperature at the second position of the condensation section 132 do not exceed the first threshold, the silent heat dissipation is continuously executed by the ionic fan 140, and the active fan 120 is not activated. If the determination result is that the temperature at the first position and the temperature at the second position of the condensation section 132 exceed the first threshold, a high load mode is entered and step S4 is executed.

In step S4, the active fan 120 is activated to operate at a first rotational speed to increase an intake volume of the cool air, and the cool air is driven by the ionic fan 140 to form the airflow flowing toward the exhaust vent 103, and forms the hot air to be discharged out of the first body 100 after the heat exchange to execute efficient heat dissipation.

During the period in which the active fan 120 operates at the first rotational speed, the processor 110 continuously reads the detection signals from the first temperature sensor 150 and the second temperature sensor 160, and determines whether the temperature at the first position of the condensation section 132 is lower than the temperature at the second position (step S5).

If the determination result is that the temperature at the first position of the condensation section 132 is lower than the temperature at the second position, it represents that the ionic airflow at the second part 1322 can still discharge the hot air out of the first body 100, so as to determine that thermal management tends toward balance, and an internal temperature of the first body 100 does not have a further rising trend. Accordingly, step S6 is executed, the processor 110 controls the driver 141 to maintain the driving voltage applied to the airflow driving modules 142 unchanged, and controls the active fan 120 to maintain operating at the first rotational speed, thus preventing increasing noise and generating unnecessary energy consumption.

If the determination result is that the temperature at the first position of the condensation section 132 is not lower than the temperature at the second position, it represents that the ionic airflow at the second part 1322 cannot discharge the hot air out of the first body 100 in time, causing heat to dissipate to the first position of the condensation section 132, so as to determine that the thermal management tends toward imbalance, and the internal temperature of the first body 100 has a further rising trend. Accordingly, step S7 is executed, whether the temperature at the first position and the temperature at the second position of the condensation section 132 of the heat pipe 130 exceed a second threshold (e.g., 60 Celsius degrees) greater than the first threshold is determined.

If the determination result is that the temperature at the first position and the temperature at the second position of the condensation section 132 exceed the second threshold, it represents that excessive heat cannot be simultaneously discharged out of the first body 100 from the first part 1321 and the second part 1322 via the ionic airflow, and step S8 is executed. In step S8, the processor 110 controls the driver 141 to increase the driving voltage applied to the airflow driving modules 142, and controls the active fan 120 to operate at a second rotational speed higher than the first rotational speed to further increase the intake volume of the cool air and accelerate the flow velocity of the airflow flowing toward the exhaust vent 103, thereby maximizing heat dissipation efficiency.

If the determination result is that the temperature at the first position and the temperature at the second position of the condensation section 132 do not exceed the second threshold, step S9 is executed. In step S9, the processor 110 controls the driver 141 to increase the driving voltage applied to the airflow driving modules 142, and controls the active fan 120 to maintain operating at the first rotational speed to accelerate the flow velocity of the airflow flowing toward the exhaust vent 103.

Compared to step S6, in step S8, by increasing the rotational speed of the active fan 120 and the driving voltage of the ionic fan 140, the intake volume of the cool air required for the heat exchange is significantly increased, and the discharge of the hot air formed after the heat exchange is accelerated. However, high-frequency noise generated by the active fan 120 operating at the high speed in step S8 is significantly higher than that in step S6. In addition, compared to step S6, in step S9, although the rotational speed of the active fan 120 remains unchanged, by increasing the driving voltage of the ionic fan 140, not only can the discharge of the hot air formed after the heat exchange be accelerated, but the intake volume of the cool air required for the heat exchange can also be slightly increased, and the high-frequency noise of step S9 is only slightly higher than that of step S6.

In the high load mode, based on real-time monitoring of the temperature at the first position and the temperature at the second position of the condensation section 132, dynamically adjusting the rotational speed of the active fan 120 and the driving voltage of the ionic fan 140 can not only provide optimal thermal management measures in response to the real-time status of the thermal management, but can also prevent the active fan 120 and the ionic fan 140 from operating at a high rotational speed and a high driving voltage for a prolonged period of time, thus preventing prolonged high-frequency noise and effectively reducing energy consumption.

Please refer to FIG. 1B, FIG. 2, and FIG. 3. In step S8, when the temperature at the first position and the temperature at the second position of the condensation section 132 exceed the second threshold, the processor 110 controls the driver 141 to increase the driving voltage applied to the airflow driving modules 142, and applies different driving voltages to the airflow driving modules 142. In detail, the driver 141 applies a first driving voltage to one airflow driving module 142 corresponding to the first position of the condensation section 132, and applies a second driving voltage to another airflow driving module 142 corresponding to the second position of the condensation section 132.

Since the temperature at the first position of the condensation section 132 is not lower than the temperature at the second position, the first driving voltage is set to be higher than the second driving voltage to guide a greater volume of the cool air to the first part 1321 of the condensation section 132, and accelerate the airflow in the region where the first part 1321 is located.

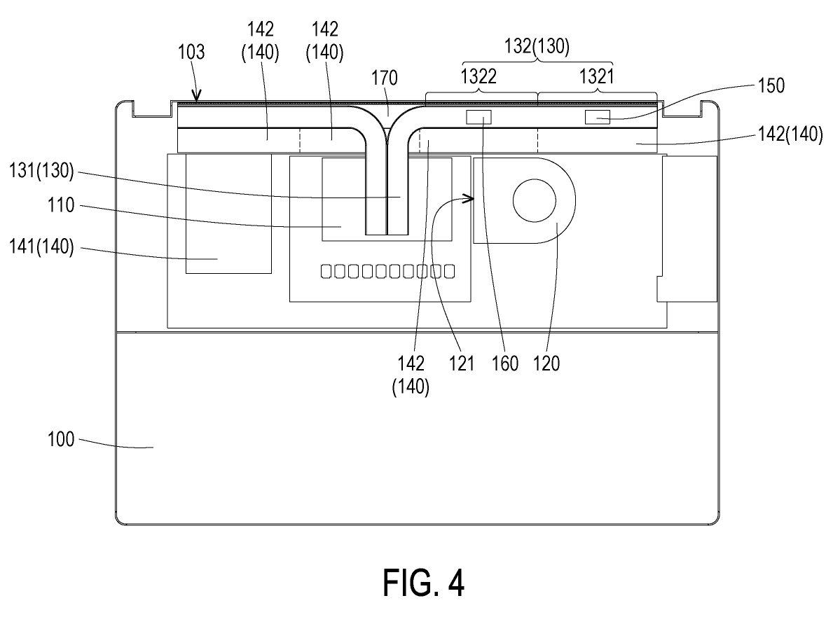

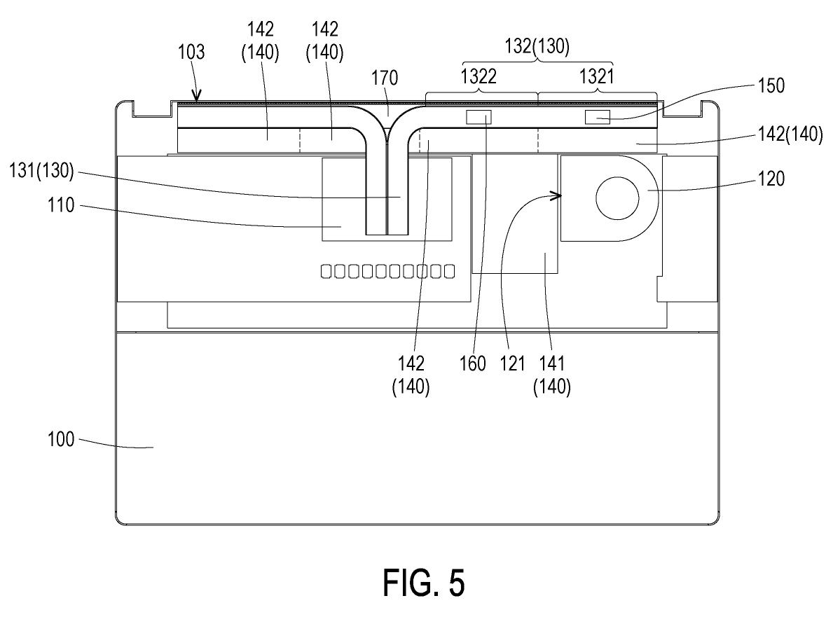

FIG. 4 and FIG. 5 are top schematic views of an internal configuration of a first body according to other embodiments of the disclosure. Please refer to FIG. 4. Different from the internal configuration of the first body 100 shown in FIG. 1B, in the embodiment, the air outlet 121 of the active fan 120 faces the heat source (i.e., the processor 110), and the heat source is located between the active fan 120 and the driver 141. Please refer to FIG. 5. Different from the internal configuration of the first body 100 shown in FIG. 1B, in the embodiment, the air outlet 121 of the active fan 120 faces the heat source (i.e., the processor 110), and the driver 141 is located between the heat source and the active fan 120. Regardless of the configuration shown in FIG. 4 or FIG. 5, the air outlet 121 of the active fan 120 is configured to more actively pre-dissipate waste heat at a front end of the heat pipe 130 and the heat source, reducing the energy consumption of the airflow driving module 142 at a rear end of the heat pipe 130 (i.e., corresponding to the second part 1322).

In summary, in the electronic device and the thermal control method thereof of the disclosure, the processor controls the ionic fan to be applied with the driving voltage in both the low load mode and the high load mode, and controls the active fan to be turned on in the high load mode. In the low load mode, the ionic fan can execute the silent heat dissipation to reduce energy consumption. In the high load mode, based on the real-time monitoring of the temperature at the first position and the temperature at the second position of the condensation section, dynamically adjusting the rotational speed of the active fan and the driving voltage of the ionic fan can not only provide the optimal heat dissipation measures in stages in response to the real-time status of the thermal management, but can also prevent the active fan and the ionic fan from operating at the high rotational speed and the high driving voltage for a prolonged period of time, preventing prolonged high-frequency noise and effectively reducing energy consumption.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. An electronic device, comprising a body and a heat source, an active fan, a heat pipe, an ionic fan, a first temperature sensor, and a second temperature sensor disposed in the body, wherein:
the body has a first side, a second side opposite to the first side, and an exhaust vent penetrating the second side,
the heat source comprises at least a processor,
the active fan is electrically coupled to the processor,
the heat pipe comprises an evaporation section and a condensation section, the evaporation section is thermally coupled to the heat source, and the condensation section extends along the exhaust vent and has a first position and a second position,
the ionic fan comprises:
a driver, electrically coupled to the processor; and
a plurality of airflow driving modules, electrically coupled to the driver, wherein the airflow driving modules are arranged along the condensation section, and the condensation section is located between the exhaust vent and the airflow driving modules,
wherein the first temperature sensor and the second temperature sensor correspond to the condensation section and are electrically coupled to the processor, the first temperature sensor is configured to detect a temperature at the first position, and the second temperature sensor is configured to detect a temperature at the second position,
wherein the processor is configured to control the driver to apply a driving voltage to the airflow driving modules and determine whether to turn on the active fan based on a determination result of the temperature at the first position and the temperature at the second position.

2. The electronic device according to claim 1, further comprising:
heat dissipation fins, arranged along the exhaust vent in the body, wherein the condensation section of the heat pipe is thermally coupled to the heat dissipation fins, and the heat dissipation fins are located between the exhaust vent and the airflow driving modules.

3. The electronic device according to claim 1, wherein the condensation section comprises a first part opposite to the evaporation section and a second part located between the first part and the evaporation section, the first position is located at the first part, the second position is located at the second part, the first temperature sensor is disposed corresponding to the first part, and the second temperature sensor is disposed corresponding to the second part.

4. The electronic device according to claim 3, wherein one side of the first part is provided with one of the airflow driving modules, and one side of the second part is provided with another one of the airflow driving modules.

5. The electronic device according to claim 1, wherein the body further has a bottom portion and an air inlet penetrating the bottom portion, and the airflow driving modules are located between the air inlet and the exhaust vent.

6. The electronic device according to claim 5, wherein the body is provided with a foot pad extending along the air inlet at the bottom portion, the foot pad has a flow guide channel communicated with the air inlet, and the flow guide channel has an opening facing the first side.

7. The electronic device according to claim 6, wherein the foot pad covers the air inlet.

8. The electronic device according to claim 1, wherein an air outlet of the active fan faces the heat source.

9. The electronic device according to claim 1, wherein the air outlet of the active fan faces the exhaust vent.

10. The electronic device according to claim 1, wherein after turning on the active fan, the processor continuously controls the driving voltage applied to the airflow driving modules by the driver and controls a rotational speed of the active fan based on the determination result.

11. The electronic device according to claim 1, wherein the processor is configured to:
receive an activation command;
control the driver to apply the driving voltage to the airflow driving modules;
determine whether the temperature at the first position and the temperature at the second position exceed a first threshold after activating the airflow driving modules; and
activate the active fan to operate at a first rotational speed when the temperature at the first position and the temperature at the second position exceed the first threshold.

12. The electronic device according to claim 11, wherein the processor is further configured to:
determine whether the temperature at the first position is lower than the temperature at the second position after activating the active fan to operate at the first rotational speed; and
maintain the driving voltage unchanged and control the active fan to maintain operating at the first rotational speed when the temperature at the first position is lower than the temperature at the second position.

13. The electronic device according to claim 12, wherein the processor is further configured to:
determine whether the temperature at the first position and the temperature at the second position exceed a second threshold when the temperature at the first position is not lower than the temperature at the second position;
increase the driving voltage and control the active fan to operate at a second rotational speed higher than the first rotational speed when the temperature at the first position and the temperature at the second position exceed the second threshold; and
increase the driving voltage and control the active fan to maintain operating at the first rotational speed when the temperature at the first position and the temperature at the second position do not exceed the second threshold.

14. The electronic device according to claim 13, wherein the processor is further configured to:
control the driver to apply different driving voltages to the airflow driving modules when the temperature at the first position and the temperature at the second position exceed the second threshold.

15. The electronic device according to claim 14, wherein the processor is configured to control the driver to apply a first driving voltage to one of the airflow driving modules corresponding to the first position, and apply a second driving voltage to another one of the airflow driving modules corresponding to the second position, wherein the first driving voltage is higher than the second driving voltage.

16. The electronic device according to claim 13, wherein the second threshold is greater than the first threshold.

17. A thermal control method of an electronic device, the electronic device comprising a body and a heat source, an active fan, a heat pipe, an ionic fan, a first temperature sensor, and a second temperature sensor disposed in the body, wherein:
the body has a first side, a second side opposite to the first side, and an exhaust vent penetrating the second side,
the heat source comprises at least a processor,
the active fan is electrically coupled to the processor,
the heat pipe comprises an evaporation section and a condensation section, the evaporation section is thermally coupled to the heat source, and the condensation section extends along the exhaust vent and has a first position and a second position,
the ionic fan comprises:
a driver, electrically coupled to the processor; and
a plurality of airflow driving modules, electrically coupled to the driver, wherein the airflow driving modules are arranged along the condensation section, and the condensation section is disposed between the exhaust vent and the airflow driving modules,
wherein the first temperature sensor and the second temperature sensor correspond to the condensation section and are electrically coupled to the processor, the first temperature sensor is configured to detect a temperature at the first position, and the second temperature sensor is configured to detect a temperature at the second position,
wherein the thermal control method comprises:
controlling, by the processor, the driver to apply a driving voltage to the airflow driving modules; and
determining, by the processor, whether to turn on the active fan based on a determination result of the temperature at the first position and the temperature at the second position.

18. The thermal control method of the electronic device according to claim 17, wherein after turning on the active fan, the processor continuously controls the driving voltage applied to the airflow driving modules by the driver and controls a rotational speed of the active fan based on the determination result.

19. The thermal control method of the electronic device according to claim 17, wherein the step of the processor controlling the driver and the active fan comprises:
receiving an activation command;
controlling the driver to apply the driving voltage to the airflow driving modules;
determining whether the temperature at the first position and the temperature at the second position of the condensation section of the heat pipe exceed a first threshold after activating the airflow driving modules; and
activating the active fan to operate at a first rotational speed when the temperature at the first position and the temperature at the second position exceed the first threshold.

20. The thermal control method of the electronic device according to claim 19, wherein the step of the processor controlling the driver and the active fan further comprises:
determining whether the temperature at the first position is lower than the temperature at the second position after activating the active fan to operate at the first rotational speed; and
maintaining the driving voltage unchanged and controlling the active fan to maintain operating at the first rotational speed when the temperature at the first position is lower than the temperature at the second position.

21. The thermal control method of the electronic device according to claim 20, wherein the step of the processor controlling the driver and the active fan further comprises:
determining whether the temperature at the first position and the temperature at the second position exceed a second threshold when the temperature at the first position is not lower than the temperature at the second position;
increasing the driving voltage and controlling the active fan to operate at a second rotational speed higher than the first rotational speed when the temperature at the first position and the temperature at the second position exceed the second threshold; and
increasing the driving voltage and controlling the active fan to maintain operating at the first rotational speed when the temperature at the first position and the temperature at the second position do not exceed the second threshold.

22. The thermal control method of the electronic device according to claim 21, further comprising:
controlling the driver to apply different driving voltages to the airflow driving modules when the temperature at the first position and the temperature at the second position exceed the second threshold.

23. The thermal control method of the electronic device according to claim 22, wherein the driver is configured to apply a first driving voltage to one of the airflow driving modules corresponding to the first position, and apply a second driving voltage to another one of the airflow driving modules corresponding to the second position, wherein the first driving voltage is higher than the second driving voltage.

24. The thermal control method of the electronic device according to claim 21, wherein the second threshold is greater than the first threshold.
